(19) United States
(12) Patent Application Publication
(10) Pub. No.: US 2024/0205856 A1
(43) Pub. Date: Jun. 20, 2024

(54) TIME ALIGNMENT OF SAMPLED RADIO FREQUENCY IN A MULTI-CHANNEL RECEIVER SYSTEM

(71) Applicant: SAAB AB, Linköping (SE)

(72) Inventors: Thomas WALLIN, Lindome (SE); Gabriel GITYE, Mölndal (SE); Rune OLSSON, Mölndal (SE)

(21) Appl. No.: 18/574,003

(22) PCT Filed: Jun. 21, 2022
(86) PCT No.: PCT/SE2022/050608

§ 371 Date: Dec. 22, 2023

(30) Foreign Application Priority Data
Jun. 23, 2021 (SE) 2100107-8

(51) Int. Cl. H04W 56/00

(52) U.S. Cl. CPC H04W 56/005

(57) ABSTRACT

The present disclosure relates to a method for synchronizing time alignment in a multi-channel radio frequency receiving system, the method including injecting an amplitude modulated reference signal into each channel in the multi-channel receiver at a location associated with each antenna input. Further, the method includes the steps of detecting a position of the reference signal within a time sample window and determining propagation time difference between each channel within the receiver electronics. Further, the method includes the steps of determining adjustment parameters, for synchronizing time alignment, for each channel and adjusting the channels in the time domain in accordance with the determined adjustment parameters of synchronization for each channel.

### TECHNICAL FIELD

The present invention relates to system and methods for time alignment in systems and in particular for time alignment of the channels in multi-channel receiving systems.

### BACKGROUND

An antenna array comprise a number of antennas that work together to perform an operation as a single antenna both as transmitter and receiving. A controlling device, for instance a transceiver or separate transmitter and receiving devices, control the signals to each antenna in order to provide a suitable functionality of the antenna array. Antenna arrays are used for controlling the radiated power in certain directions and/or for controlling the receiving directivity in multi-channel receiving systems.

Generally, multi-channel receiving systems find applicability in wireless telecom applications, radar applications, wireless networks, broadcasting, and other communications applications.

Signal reception problems is an occurrence in multi-channel receiving systems. A common issue that may cause this is that there is differences in delays in time-domain between the channels of the multi-channel receiving system. Preferably, the delay between each channel in a multi-channel receiving system is below specific levels. However, obtaining a desired difference in delays between channels is often challenging, and in some cases impossible to construct, when providing multi-channel receiving systems. Desired levels of delays between channels in a multi-channel receiving system need to be achieved in order to ensure a proper functioning of the system. However, to reach the desired levels, there is a need to calibrate the system in an efficient, rapid and accurate manner.

There is a need in the present art to provide multi-channel receiving systems having means for calibration delay equality between all receiving channels in a rapid, efficient and accurate manner. Thus, there is room for multi-channel receiving systems in the present art to explore the domain of providing multi-channel receiving systems having efficient, rapid and accurate calibration means for achieving time-alignment between channels in multi-channel receiving systems.

Even though previous solutions may work well, it is desirable to provide a multi-channel receiving system and method for operating such to address requirements related to improving time-alignment between the channels in a multi-channel receiving. Specifically there is a need in the present art to provide a multi-channel receiving systems and method for operating such for synchronizing time alignment in a multi-channel radio frequency receiving system in an efficient, rapid and accurate manner.

### SUMMARY

It is therefore an object of the present disclosure to provide methods and systems to mitigate, alleviate or eliminate one or more of the above-identified deficiencies and disadvantages.

This object is achieved by means of a system, receiver and a method as defined in the appended claims.

The present disclosure is disclosed by the subject-matter of the independent claims. The present disclosure is at least partly based on the insight that by providing a method, a receiver and a system that improves time-alignment between the channels in a multi-channel receiving system, there will be provided a better performance of such systems, receivers and methods for operating such.

The present disclosure provides a method for synchronizing time alignment in a multi-channel radio frequency receiving/receiver system, the method comprising the steps of:
injecting an amplitude modulated or phase modulated reference signal into each channel in the multi-channel receiver at a location associated with each antenna input.
detecting a position of the reference signal within a time sample window for each channel after analog to digital conversion of said reference signal;
determining propagation time difference and digital synchronization error of the reference signal between each channel within the receiver system;
determining adjustment parameters, for synchronizing time alignment, for each channel;
adjusting the channels in the time domain in accordance with the determined adjustment parameters of synchronization for each channel.

A benefit of the method is that it allows for synchronizing time alignment between channels thus allowing the receiver to operate to a better performance e.g. in to suppress side-lobes in radar system it's of importance to have time-alignment between channels in a receiver system. Also, the method in the present disclosure utilizes a digital adjustment in order to synchronize channels, which is more cheap and convenient to implement compared to previous solutions utilizing e.g. phase matching cables. Accordingly, the method provides the benefit of allowing for synchronization of multiple channels which may be subject to analog propagation delay and digital synchronization error.

Moreover, by using an amplitude modulated signal, injected prior to any signal conversions, the detecting of the positions in the time sample window is more rapid and convenient allowing the signal waves of said amplitude modulated signal to be unaffected by the receiver channels. Moreover, the method utilizing means to detect position of the reference signal within a time sample window, allows for an accurate estimation of the propagation time difference and digital synchronization error, thus also allowing for an accurate compensation/calibration of the receiver system. It should be noted that the disclosure may use a phase modulated signal.

The channels may be adjusted in the time domain by at least one of:
a coarse delay shift in the order of an integer number of analog-to-digital conversion (ADC) samples; and
a fine delay shift in the order of a fractional of ADC samples in accordance with the determined parameters for synchronization for each channel.

A benefit of this is that the channels may be adjusted in a flexible manner and to a high accuracy. The system may adjust the channels in different ways in different situations. By utilizing both adjustments, the adjustment may be performed to a higher accuracy. However, in some embodiments only a coarse delay shift may be sufficient to achieve a desired time-alignment between the channels.

The reference signal may be a saw tooth signal (i.e. triangular amplitude modulated signal), or any other suitable type of signal having a (well) defined function (i.e. reference point).

A benefit of this is that it allows for an easier determining of propagation time difference and digital synchronization error of the reference signal. A saw tooth signal comprises a well-defined function, with a well-defined reference point, making it easier to defined and determine time difference between the reference signals in each channel.

The saw tooth signal may have a rise and fall time in the order of 1 μs. Allowing for a sufficient sample window where compensation may be determined to high accuracy and speed. In some embodiments, the rise and fall time is between 1-5 μs.

The step of adjusting the channels may comprise using an interpolation filter. A benefit of this is that it may provide for a more flexible accuracy in the adjustment.

The interpolation filter may operate steps of up-sampling, sample delay, and down-sampling in an interpolation module.

The step of adjusting the channels may comprise at least one of using a shift register, and controlling a clock generation circuit of the ADC to adjust the phase of the outgoing signal.

The synchronization may be performed at startup of the system. A benefit of this is that the method allows for the synchronization to be applied throughout the system running. In other words, only one synchronization procedure is needed to get the system at a desired operating level.

However, the synchronization may be checked at pre-set intervals during operation of the system. So to ensure proper functioning of the system.

The step of determining propagation time difference and digital synchronization error may comprises for each channel, determining an actual sample distribution around a reference point in a pre-determined sample area in each of said time sample windows. Further, setting a desired sample distribution having evenly distributed samples around said reference point. Further, determining a difference between each desired sample distribution and each actual sample distribution for each channel and also to compare the difference between the channels. It should be noted that the method may adjust the digital synchronization error, while taking into account the analog propagation time difference. Thus, the adjustment in accordance with the present disclosure is a digital adjustment.

A benefit of this is that it allows for an efficient determination of the time difference which can be rapidly performed. Thus, allowing for an optimized compensating procedure. Preferably, the reference point is a center point in said pre-determined sample area, allowing for a more accurate determination of the time difference, since samples will be spread around a center point.

The detector unit and the calibration reference signal can be adjusted to the time accuracy requirement. The detector unit may generate a detector signal proportional to a time delay with the formula:

$$Detector = {\sum }_{k = 1}^{N / 2} \sqrt{( {I}_{k}^{2} + {Q}_{k}^{2} )} - {\sum }_{l = \frac{N}{2} + 1}^{N} \sqrt{( {I}_{l}^{2} + {Q}_{l}^{2} )}$$

over N reference signal samples.

There is further provided a radio-frequency receiving system for synchronizing time delays in different receiver channels, the system comprising a plurality of antennas having antenna inputs, a plurality of receiver channels, control circuitry. The control circuitry is configured to:
inject an amplitude modulated or phase modulated reference signal into each channel in the multi-channel receiver at a location associated with each antenna input.
detect a position of the reference signal within a time sample window for each channel after analog to digital conversion.
determine propagation time difference and digital synchronization error between each channel.
determine adjustment parameters, for synchronizing time alignment, for each channel.
adjust the channels in the time domain in accordance with the determined adjustment parameters of synchronization for each channel.

There is further provided a computer-readable storage medium storing one or more programs configured to be executed by one or more control circuitry of a radio frequency receiver system, the one or more programs comprising instructions for performing the method according to the present disclosure.

Further there is provided a vehicle comprising the receiving system according to the present disclosure. The vehicle may be a ground-based vehicle or an airborne vehicle.

### BRIEF DESCRIPTION OF THE DRAWINGS

In the following the invention will be described in a non-limiting way and in more detail with reference to exemplary embodiments illustrated in the enclosed drawings, in which:

FIG. 1 is a schematic block diagram illustrating a method in accordance with an embodiment of the present disclosure;

FIG. 2 is a schematic block diagram illustrating alignment between Rx channels prior to and after adjustment;

FIG. 3 is an exemplary graph illustrating sample distribution around a reference point in a pre-determined sample area in a channel of a receiver system, after time alinement (delay) calibration;

FIG. 4 is an exemplary graph illustrating sample distribution around a reference point in a pre-determined sample area in a channel of a receiver system, before time alinement (delay) calibration;

FIG. 5 is a schematic block diagram illustrating a multi-channel receiver system and specifically illustrating circuitry in the system for channel synchronization in accordance with an embodiment of the present disclosure;

FIG. 6 is a schematic view illustrating a RF system shown in FIG. 5;

FIG. 7 is a schematic view illustrating a multi-channel receiver system in accordance with an embodiment of the present disclosure; and

FIG. 8 is a schematic view of a vehicle comprising the system in accordance with an embodiment of the present disclosure.

FIG. 9 is a schematic illustration of Rx channels prior to and after channel synchronization between the channels in accordance with an exemplary embodiment of the present disclosure.

### DETAILED DESCRIPTION

It should be noted that the word “comprising” does not exclude the presence of other elements or steps than those listed and the words “a” or “an” preceding an element do not exclude the presence of a plurality of such elements. It should further be noted that any reference signs do not limit the scope of the claims, that the disclosure may be at least in part implemented by means of both hardware and software, and that several “means” or “units” may be represented by the same item of hardware.

The above mentioned and described embodiments are only given as examples and should not be limiting to the present invention. Other solutions, uses, objectives, and functions within the scope of the disclosure as claimed in the below described patent embodiments should be apparent for the person skilled in the art.

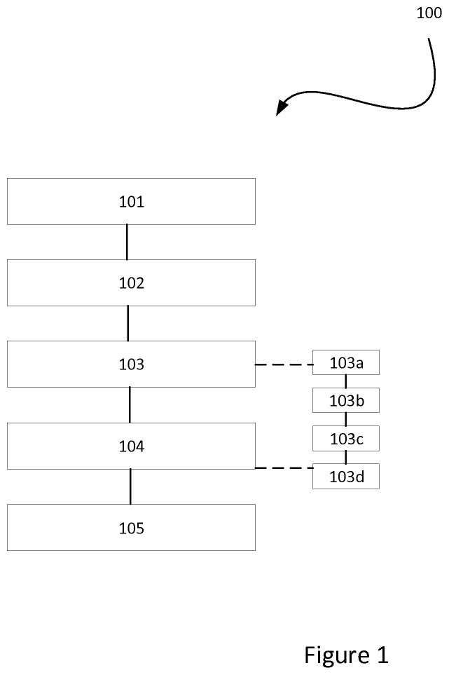

FIG. 1 illustrates a flowchart of a method for 100 for synchronizing time alignment in a multi-channel radio frequency receiving system, the method comprising the steps of injecting 101 an amplitude modulated (or phase modulated) reference signal into each channel in the multi-channel receiver at a location associated with each antenna input. Further comprising the steps of detecting 102 a position of the reference signal within a time sample window for each channel after analog to digital conversion. Further, the method comprises the step of determining 103 propagation time difference and digital synchronization error between each channel within the receiver electronics (preferably within a detector unit). Further, the method comprises the step of determining 104 adjustment parameters (based on the propagation time difference), for synchronizing time alignment, for each channel. Moreover, the method adjusts 105 the channels in the time domain in accordance with the determined adjustment parameters of synchronization for each channel.

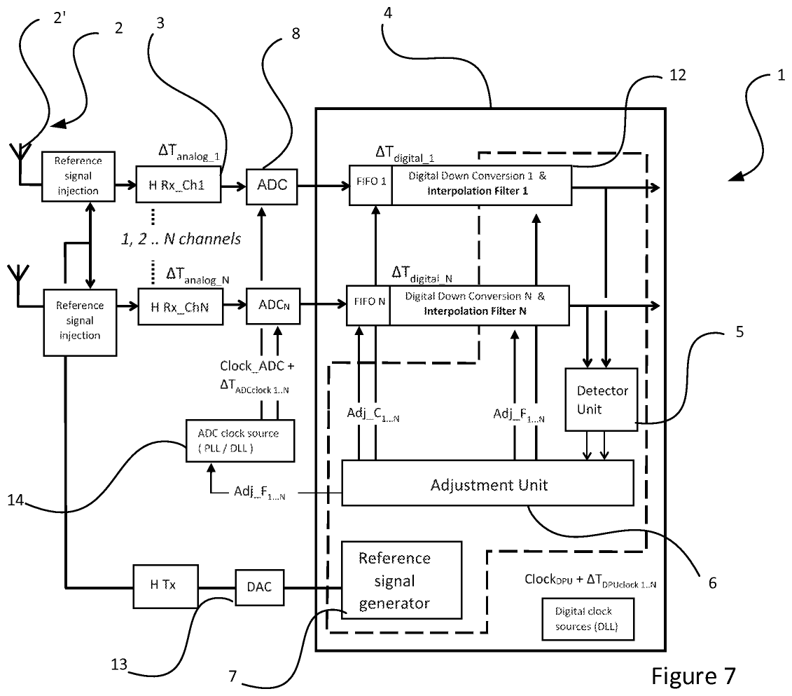

The step of adjusting 105 the channels may comprise using an interpolation filter. The interpolation filter may operate steps of up-sampling, sample delay, and down-sampling in an interpolation module. Further, the step of adjusting 105 the channels may comprise at least one of using a shift register, and controlling a clock generation circuit 14 (shown in FIG. 7) of the ADC to adjust the fine time delay (i.e. may be operated to fine delay shift) of the outgoing signal. The adjusting allows the channels to be synchronized.

As further shown in FIG. 1, the step of determining 103 propagation time difference and digital synchronization error may comprise, for each channel, determining 103a an actual sample distribution around a reference point in a pre-determined sample area in each of said time sample windows. Further, setting 103b a desired sample distribution having evenly distributed samples around said reference point. Moreover, determining 103c a difference between each desired sample distribution and each actual sample distribution for each channel. Furthermore, comparing 103d the difference between the channels.

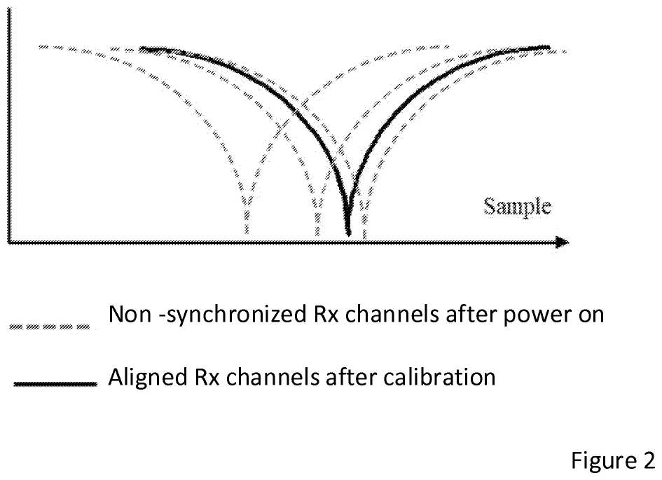

FIG. 2 illustrates a graph showing the receiver channels prior to synchronization (showing a plurality of dotted lines), i.e. non synchronized Rx channels, further, the graph also shows the aligned Rx channels after synchronizing/calibrating the Rx channels in accordance with the method 100 of the present disclosure. Thus, showing time-aligned Rx channels.

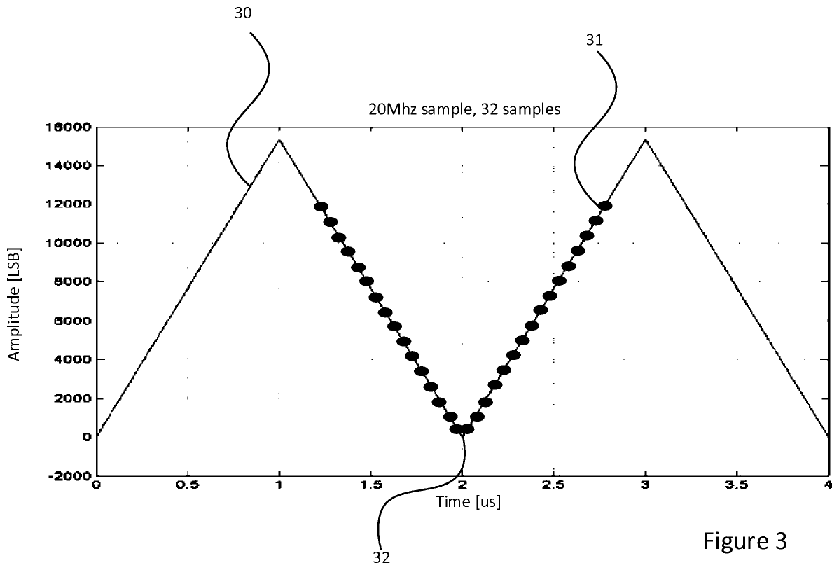

FIG. 3 illustrates an exemplary graph showing the detection 102 of a position of the reference signal 30 within a time sample window. In detail, FIG. 3 shows an actual sample distribution 31 around a reference point 32 in a pre-determined sample area. This may further be compared with a desired sample distribution so to determine a difference between the desired and the actual sample distribution 31 so compare difference between the channels.

In FIG. 3, the samples 31 are evenly distributed around the reference point 32 (16 sample points on respective side of the reference point). Thus, the actual sample distribution is equal to the desired sample distribution in FIG. 3. Thus, the sample for the channel of FIG. 3 does not need any adjusting. However, for other channels in the receiver system where the samples are not distributed according to the desired manner, the channels need adjusting so to be aligned in the manner shown in FIG. 3.

In FIG. 3, the reference point 32 is a center point in said pre-determined sample area. However, in some embodiments, the reference point 32 is not necessarily a center point. Further, the reference signal 30 may be a saw tooth signal as shown in FIG. 3, however, said signal 30 is not restricted to a saw-tooth signal. The saw tooth signal may have a rise and fall time in the order of 1 μs. Further, the number of sample points may be any arbitrary number of sample points.

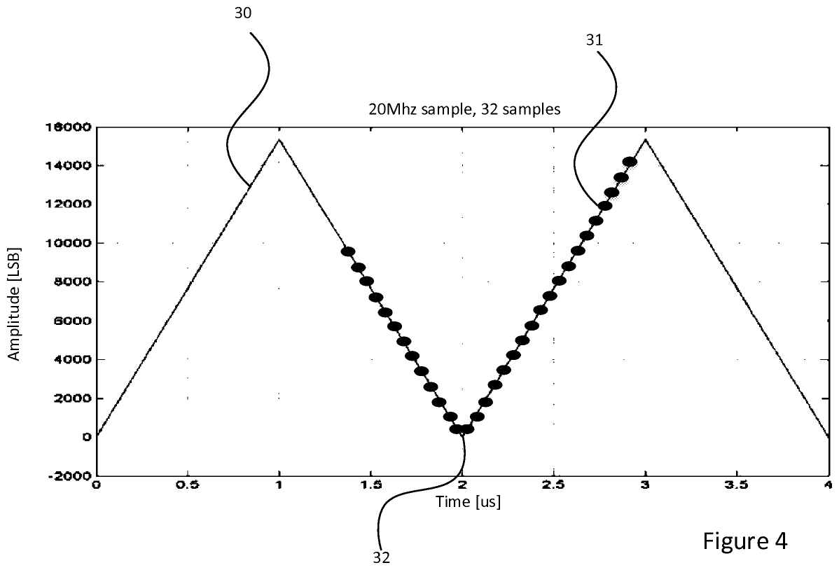

FIG. 4 illustrates an exemplary graph showing the detection of a position of the reference signal 30 within a time sample window for another channel (different from the one shown in FIG. 3) in a common RF receiving system 1. In detail, FIG. 3 shows an actual sample distribution 31 around a reference point 32 in a pre-determined sample area. As seen in FIG. 4, the 32 samples are not evenly distributed around said reference point 32, thus, adjustment is needed in order to align said channel with the channel in FIG. 3. Accordingly, FIGS. 3 and 4 may show non-synchronized channels in a receiver system, by adjusting the channels in FIG. 4 in accordance with the method 100, the two channels may be synchronized. It should be noted that the area of the time sample window and the reference points may be varied.

The channels may be adjusted in the time domain by at least one of a coarse delay shift in the order of an integer number of analog-to-digital conversion, ADC, samples, and a fine delay shift in the order of a fractional of ADC samples in accordance with the determined parameters for synchronization for each channel.

The method 100 in accordance with the present disclosure may be performed at startup of the system. Thus, ensuring proper functioning from the initial startup of the RF receiving system. However, the synchronization between the channels of the system may be checked at pre-set intervals during operation of the system.

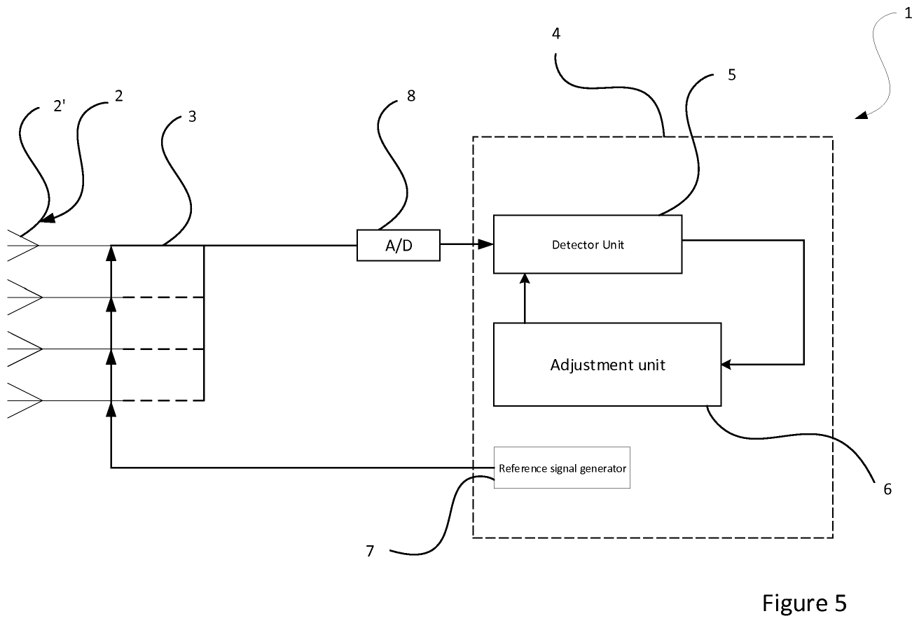

FIG. 5 illustrates an RF receiving system 1 for synchronizing time delays in different receiver channels 3, the system comprising, a plurality of antennas 2 having antenna inputs 2′, a plurality of receiver channels 3 and control circuitry 4. The control circuitry 4 is configured to inject an amplitude modulated (or phase modulated which then is amplitude modulated at a later stage in the circuitry) reference signal into each channel 3 in the multi-channel receiver 1 at a location associated with each antenna input 2′. Further, the control circuitry 4 is configured to detect a position of the reference signal within a time sample window for each channel 3 after analog to digital conversion. Further, determine propagation time difference and digital synchronization error between each channel 3 and adjustment parameters, for synchronizing time alignment, for each channel 3. Moreover, the control circuitry 4 adjusts the channels in the time domain in accordance with the determined adjustment parameters of synchronization for each channel 3.

FIG. 5 shows that the control circuitry 4 comprises a detector unit 5, an adjustment unit 6 and a reference signal generator 7. The reference signal generator may be configured to inject an amplitude modulated (or phase modulated which then is amplitude modulated at a later stage in the circuitry) reference signal into each channel 3 in the multi-channel receiver 1 at a location associated with each antenna input 2′.

The detector unit 5 may be configured to detect a position of the reference signal within a time sample window for each channel 3 after analog to digital conversion performed by the A/D converter 8. Further, the detector unit 5 may be configured to determine propagation time difference and digital synchronization error between each channel 3 and adjustment parameters, for synchronizing time alignment, for each channel 3. Thus, adjustment parameters may be time-parameters.

Further, the adjustment unit 6 may be configured to adjust the channels in the time domain in accordance with the determined adjustment provided by the detector unit 5. The adjustment unit 6 and the detector unit 5 may be integrated.

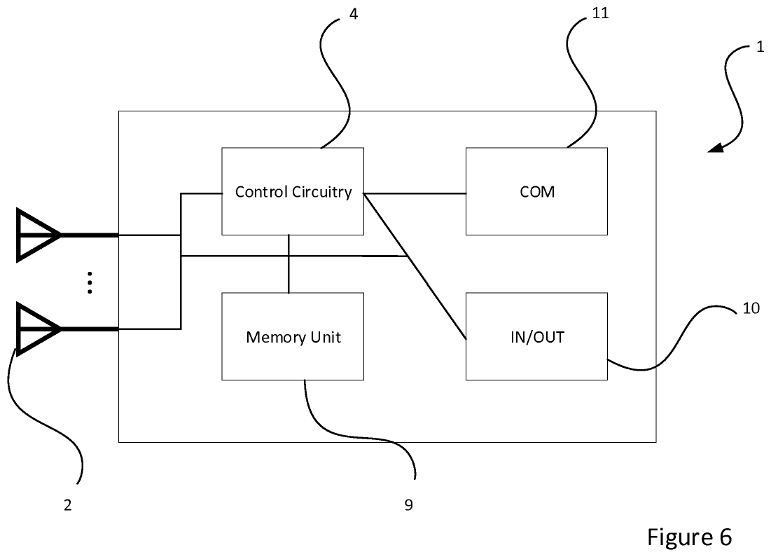

FIG. 6 schematically illustrates components of the receiving system 1 shown in FIG. 5 schematically. As seen in FIG. 6, the receiving system 1 may further comprise at least one memory unit 9, an input/output interface 10 and optionally at least one communication interface 11. In FIG. 5 the input and output interface 10 are integrated, however they may be separate modules in some embodiments of the present disclosure. The input/output interface 10 may be connected to the antennas.

The at least one memory unit 9 may comprise any form of volatile or non-volatile computer readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device readable and/or computer-executable memory devices that store information, data, and/or instructions that may be used.

The control circuitry 4 may be arranged to run instruction sets in the memory unit 9 for operating the method 100. The control circuitry 4 may be any suitable type such as a microprocessor, digital signal processor (DSP), ASIC (Application Specific Integrated Circuit), FPGA (Field Programmable Gate Array), or a combination of these, or other similar processing means arranged to run instruction sets. The computer readable storage medium may be of non-volatile and/or volatile type and transitory or non-transitory type; for instance RAM, EEPROM, flash disk and so on. It should be noted that the memory unit 9 may be integrated with the control circuitry 4. Further, each of the detector unit 5, adjustment unit 6, and reference signal generator 7 shown in FIG. 5 may comprise a memory unit 9, input/output interface 10 and communication interface 11 respectively.

The communication interface 11 may be of any suitable type such as Ethernet, I2C bus, RS232, CAN bus, wireless communication technology such as IEEE 802.11 based or cellular based technologies, or other communication protocols depending on application. The communication interface 11 may be used for receiving signals from the antennas 2, software updates, and instruction messages for determining the status of the receiving system 1. Furthermore, the communication interface 11 may be used to communicate results, messages, status reports and similar to external devices and control units such as a control station or servers via a network, e.g. via public or private networks. The networks may be local or wide area networks depending on the use of receiving system 1. For instance in a radar station such as a mobile radar station the network can be located in a vehicle. In case of a radar station for an airport, the network can be local for the airport or a wide area network for a remotely controlled airport. Furthermore, the network may be utilized as a private network or a public network such as the Internet, in a cloud solution.

FIG. 7 illustrates the system 1 in accordance with some embodiments, wherein the system 1. FIG. 7 shows that the system 1 further comprises at least one interpolation module 12. The at least one interpolation module 12 may operate steps of up-sampling, sample delay, and down-sampling. As shown in FIG. 7, each channel 3 may be connected to a corresponding ADC 8 and interpolation module 12.

The system 1 may further comprise a digital to analog converter 13 configured to convert the amplitude modulated (or phase modulated) reference signal generated by the reference signal generator 7 so to inject the analog signal close to the antenna input 2′.

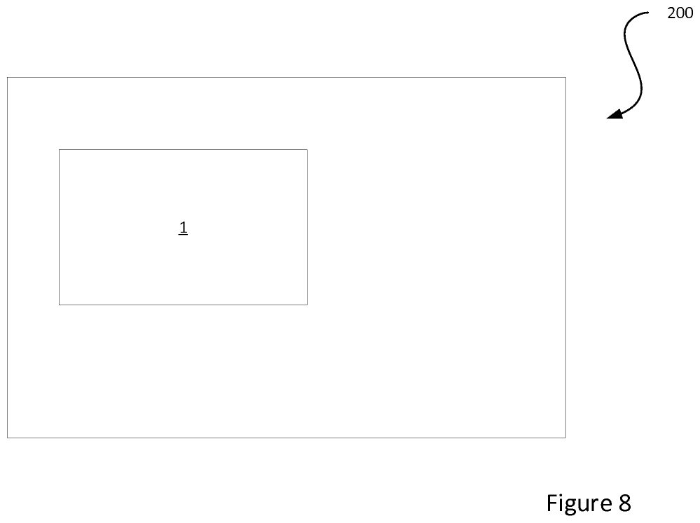

FIG. 8 illustrates a vehicle 200 comprising the RF receiving system 1 in accordance with an embodiment of the present disclosure.

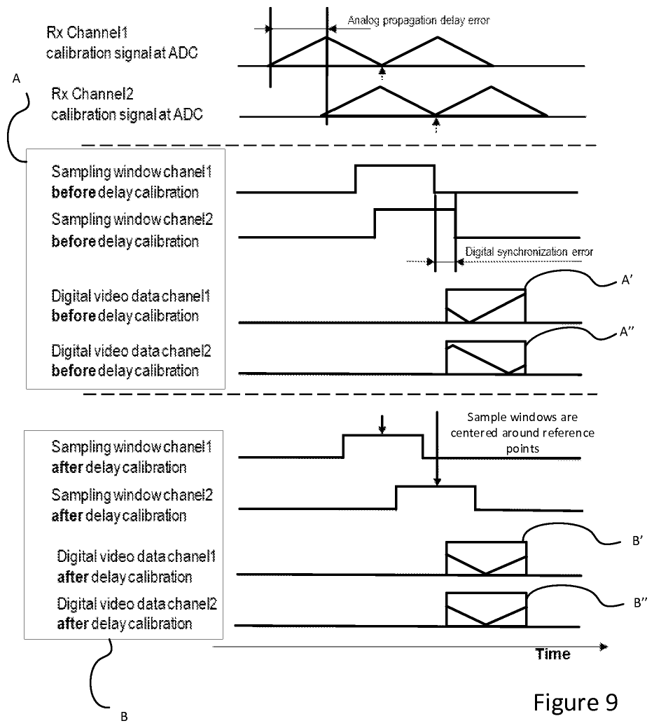

FIG. 9 illustrates a graph showing two receiver channels (Rx Channel 1 and Rx Channel 2) schematically over a time period in accordance with an exemplary simulation of the present disclosure. FIG. 9 shows the channels prior to calibration/synchronization in accordance with the present disclosure showing that there is an analog propagation delay and also a digital synchronization error in-between the channels after injection of reference/calibration signal. It is shown that the digital video data channel 1 and channel 2 before delay calibration (which is seen in the box denoted by the reference letter A) has a differing signal in the time sample windows which is evident from reference letter A′ and A″ (i.e. apparent after the step of detecting 102). Thus, in order to adjust the delay/errors in accordance with the present disclosure, the propagation time difference and digital synchronization error may be determined 103 (or e.g. in accordance with the embodiment comprising the step of 103a-103d) so to derive adjustment parameters.

Further, FIG. 9 shows the channels after the calibration/synchronization of time alignment in accordance with some of the embodiments of the present disclosure, which is denoted by the reference letter B showing that the digital video after calibration is fully synchronized between the channels. Thus, after determining propagation error and digital synchronization error/difference between the channels (e.g. by method step 103 or 103a-103d), the channels may be adjusted so to be synchronized i.e. resulting in that the sample windows are centered around a reference point (evident from reference letters B′ and B″), accordingly the digital video data channel for both channels (rx 1 and rx 2) are synchronized. Thus, the present disclosure may account for both digital and analog errors/delays and adjust accordingly. Digital sync-errors may be caused by differences in start-sync-arrival, clock phase differences or other causes. Analog propagation delay may be caused by, e.g. different cable lengths.

1. A method for synchronizing time alignment in a multi-channel radio frequency receiving system, the method comprising:
injecting an amplitude modulated or phase modulated reference signal into each channel in the multi-channel receiver at a location associated with each antenna input;
detecting a position of the reference signal within a time sample window for each channel after analog to digital conversion;
determining propagation time difference and digital synchronization error between each channel within the receiver electronics;
determining adjustment parameters, for synchronizing time alignment, for each channel;
adjusting the channels in the time domain in accordance with the determined adjustment parameters of synchronization for each channel.

2. The method according to claim 1, wherein the channels are adjusted in the time domain by at least one of:
a coarse delay shift in the order of an integer number of analog-to-digital conversion, ADC, samples; and
a fine delay shift in the order of a fractional of ADC samples in accordance with the determined parameters for synchronization for each channel.

3. The method according to claim 1, wherein the reference signal is a saw tooth signal.

4. The method according to claim 3, wherein the saw tooth signal has a rise and fall time in the order of 1 μs.

5. The method according to claim 1, wherein adjusting the channels comprise using an interpolation filter.

6. The method according to claim 5, wherein the interpolation filter operates steps of up-sampling, sample delay, and down-sampling in an interpolation module.

7. The method according to claim 1, wherein adjusting the channels comprise at least one of using a shift register, and controlling a clock generation circuit of the ADC to adjust the phase of the outgoing signal.

8. The method according to claim 1, wherein the synchronization is performed at startup of the system.

9. The method according to claim 1, wherein the synchronization is checked at pre-set intervals during operation of the system.

10. The method according to claim 1, wherein the step of determining propagation time difference and digital synchronization error comprises:
for each channel, determining an actual sample distribution around a reference point in a pre-determined sample area in each of said time sample windows;
setting a desired sample distribution having evenly distributed samples around said reference point;
determining a difference between each desired sample distribution and each actual sample distribution for each channel;
comparing the difference between the channels.

11. The method according to claim 10, wherein the reference point is a center point in said pre-determined sample area.

12. A radio-frequency, (RF) receiving system for synchronizing time alignment in different receiver channels, the RF receiving system comprising:
a plurality of antennas having antenna inputs;
a plurality of receiver channels;
control circuitry;
wherein the control circuitry is configured to:
inject an amplitude modulated or phase modulated reference signal into each channel in the RF receiver system at a location associated with each antenna input;
detect a position of the reference signal within a time sample window for each receiver channel after analog to digital conversion;
determine propagation time difference and digital synchronization error between each channel;
determine adjustment parameters, for synchronizing time alignment, for each channel;
adjust the channels in the time domain in accordance with the determined adjustment parameters of synchronization for each channel.

13. A non-transitory computer-readable storage medium storing one or more programs configured to be executed by one or more control circuitry of a multi-channel radio frequency receiver system, the one or more programs comprising instructions for performing the method according to claim 1.

14. A vehicle comprising the RF receiving system according to claim 12.
